(19) United States
(12) Patent Application Publication
(10) Pub. No.: US 2026/0305229 A1
(43) Pub. Date: Oct. 1, 2026

(54) SUBSTRATE PROCESSING APPARATUS

(71) Applicant: SCREEN Holdings Co., Ltd., Kyoto (JP)

(72) Inventors: Tomoaki AIHARA, Kyoto (JP); Tetsuya WATANABE, Kyoto (JP)

(21) Appl. No.: 19/569,331

(22) Filed: Mar. 17, 2026

(30) Foreign Application Priority Data
Mar. 25, 2025 (JP) 2025-049598

(51) Int. Cl. H10P 72/00

(52) U.S. Cl. CPC H10P 72/0448; H10P 72/0434; H10P 72/0602

(57) ABSTRACT

A substrate processing apparatus comprises a processing liquid supplier which outputs a temperature-regulated processing liquid, a substrate processor which processes a substrate using the processing liquid, and an interconnecting pipe connecting the processing liquid supplier and the substrate processor to each other and passing the processing liquid therethrough. The interconnecting pipe includes a processing liquid pipe and an exterior pipe having a hollow internal space in which the processing liquid pipe is inserted, and a spacer arranged between the processing liquid pipe and the exterior pipe in the internal space to maintain an outer wall surface of the processing liquid pipe and an inner wall surface of the exterior pipe in a non-contact state. The spacer includes a flow path forming part functioning as a gas flow path allowing gas to pass therethrough in a pipe axis direction of the processing liquid pipe in the internal space.

### CROSS REFERENCE TO RELATED APPLICATION

The disclosure of Japanese Patent Application No.2025-049598 filed on Mar. 25, 2025 including specification, drawings and claims is incorporated herein by reference in its entirety.

### BACKGROUND OF THE INVENTION

### 1. Field of the Invention

This invention relates to a substrate processing apparatus for processing a substrate using a temperature-regulated processing liquid.

### 2. Description of the Related Art

In a process of manufacturing various kinds of substrates such as semiconductor substrates or glass substrates, for example, processing liquids at various temperatures having various compositions are used for processing the substrates. In some cases, water prepared by cooling high-purity water such as de-ionized water or pure water to a temperature around its freezing point (0°C) (resultant water is simply called “cool water” herein) is required to be used as these processing liquids. As an example, according to a technique shown in JP2024-134431A (Patent Literature 1) disclosed previously by the applicant of the present application, de-ionized water (DIW) temperature-regulated to a low temperature is used as a cooling medium and brought into contact with a back surface of a substrate for the purpose of cooling the substrate heated during a course of a process.

While Patent Literature 1 does not provide specific mention, as control for highly-clean atmosphere is required in a process handling a semiconductor substrate, a substrate processor responsible for an actual process on the substrate and a processing liquid supplier for preparing a processing liquid necessary for the process are configured as devices independent of each other, and in many cases, these units are installed at separate positions. Thus, in one case, for supplying the processing liquid from the processing liquid supplier to the substrate processor, the processing liquid supplier and the substrate processor are connected to each other using a pipe called an interconnecting pipe having a comparatively large flow path length and extending to the outside of an apparatus.

In passing the cooled processing liquid using the above interconnecting pipe, the pipe and an atmosphere around the pipe are further cooled by the processing liquid at a low temperature. This may cause water droplets resulting from dew condensation in an environment where the apparatus is installed. Patent Literature 1 does not provide statement of such a problem.

Meanwhile, if the pipe is a so-called soft pipe made of a flexible resin material, for example, a double pipe is widely used in order to compensate for the low mechanical strength of the pipe. This pipe has a configuration where a pipe for causing the processing liquid to flow therein is arranged in a protective pipe having a larger diameter. With this configuration, it is possible to protect the pipe mechanically, and even on the occurrence of leakage of the processing liquid from the pipe, it is still possible to prevent leakage of the processing liquid to the outside using the protective pipe.

While the double pipe is expected to fulfill a certain degree of effect in response to the problem of dew condensation, this effect is not sufficient. Reason for this is that, as the double pipe intended for protection is not always expected to fulfill heat-insulating effect, the temperature of the protective pipe may decrease to cause dew condensation if the pipe for the processing liquid and the protective pipe come into contact with each other to generate a heat bridge at a place of the contact, for example.

In addition to the problem of dew condensation, move of heat energy increases the temperature of the processing liquid, failing to supply the processing liquid at a requested temperature to the substrate processor. This problem also applies if the processing liquid in a warmed state is passed through the interconnecting pipe. The problem that might occur in this case is that heat energy of the warmed processing liquid is lost to decrease the temperature of the processing liquid.

### SUMMARY OF THE INVENTION

This invention has been made in view of the above problem. In a substrate processing apparatus where a temperature-regulated processing liquid is passed through an interconnecting pipe, the invention is intended to provide a technique capable of resolving a problem such as temperature change or dew condensation by reducing heat loss of the processing liquid to flow in a pipe.

One aspect of the present invention is intended for a substrate processing apparatus comprising: a processing liquid supplier configured to output a temperature-regulated processing liquid; a substrate processor configured to process a substrate using the processing liquid supplied from the processing liquid supplier; and an interconnecting pipe connecting the processing liquid supplier and the substrate processor to each other and used for passing the processing liquid therethrough. The interconnecting pipe includes: a processing liquid pipe for causing the processing liquid to flow therein; an exterior pipe configured to have a hollow internal space in which the processing liquid pipe is inserted, thereby to cover a periphery of the processing liquid pipe; and a spacer member arranged between the processing liquid pipe and the exterior pipe in the internal space, and configured to maintain an outer wall surface of the processing liquid pipe and an inner wall surface of the exterior pipe in a non-contact state. The spacer member includes a flow path forming part functioning as a gas flow path configured to allow gas to pass therethrough in a pipe axis direction of the processing liquid pipe in the internal space.

According to the invention having the above configuration, the interconnecting pipe has a so-called double pipe configuration where the processing liquid pipe is arranged inside the exterior pipe. Furthermore, by the presence of the spacer member provided between the inner wall surface of the exterior pipe and the outer wall surface of the processing liquid pipe arranged inside the exterior pipe, contact between the both pipes is avoided. This prevents formation of a heat bridge due to contact between the processing liquid pipe and the exterior pipe, thereby suppressing move of heat energy of the processing liquid to the outside.

In this case, the spacer member itself might become a heat bridge. However, as the configuration of the spacer member does not affect flow of the processing liquid, loss of the heat energy can be suppressed by selecting a material, shape, etc. of the spacer member appropriately. Moreover, as the configuration of the spacer member is known, the magnitude of the loss can be estimated in advance for taking action against the loss.

Further, at the spacer member used in the present invention, it is possible to cause the gas to flow in the pipe axis direction of the processing liquid pipe in the internal space of the exterior pipe. Specifically, the spacer member does not hinder flow of the gas in a space between the processing liquid pipe and the exterior pipe. As a result, it is possible to perform atmosphere control for eliminating stay of the gas in this space, and collect the processing liquid leaking from the processing liquid pipe without causing flowing out thereof to the outside. Thus, the spacer member does not become a factor for losing the advantage of the double pipe configuration.

As described above, according to the present invention, in the double pipe configuration including the processing liquid pipe and the exterior pipe, the processing liquid pipe and the exterior pipe are separated from each other by the spacer member provided therebetween, and the gas flow path is formed in the space between the pipes. This makes it possible to settle the problems of temperature change of the processing liquid, dew condensation and others to be caused by move of heat across a heat bridge without losing the advantage of the double pipe configuration.

The above and further objects and novel features of the invention will more fully appear from the following detailed description when the same is read in connection with the accompanying drawing. It is to be expressly understood, however, that the drawing is for purpose of illustration only and is not intended as a definition of the limits of the invention.

### BRIEF DESCRIPTION OF THE DRAWINGS

FIG. 1 shows a schematic configuration of a substrate processing system according to one embodiment of the present invention;

FIG. 2 shows an exemplary configuration of the cooling device;

FIGS. 3A - 3C show an exemplary configuration of the heat exchanger;

FIG. 4 shows layout of the substrate processing system and an example of an interconnecting pipe;

FIGS. 5A and 5B show the configuration of a pipe applicable as the feed pipe;

FIGS. 6A - 6E show the configuration of the spacer;

FIGS. 7A - 7C show a modification of the feed pipe; and

FIGS. 8A- 8C show exemplary configurations of the double pipe for the spacer.

### DETAILED DESCRIPTION OF THE PREFERRED EMBODIMENTS

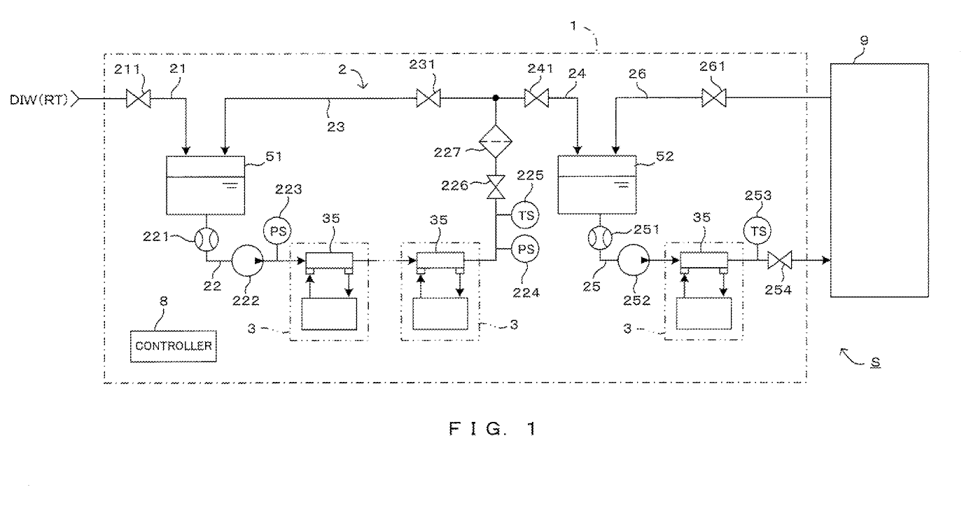

FIG. 1 shows a schematic configuration of a substrate processing system according to one embodiment of the present invention. This substrate processing system S includes a processing liquid supplier 1 and a substrate processor 9. The processing liquid supplier 1 cools pure water or de-ionized water supplied from an external supply source to a predetermined temperature and outputs the cooled water as a processing liquid. The substrate processor 9 processes a processing target substrate using the processing liquid supplied from the processing liquid supplier 1. In the following, DIW will be described as a representative of the processing liquid. The substrate processor 9 may be configured to supply this processing liquid as it is to the substrate, or may be configured to mix the processing liquid with a different type of chemical or an organic solvent such as isopropyl alcohol (IPA) and supply a resultant liquid to the substrate, for example. While a semiconductor wafer is applicable as the substrate to be processed, for example, the substrate is not limited to this. While a representative process by the substrate processor 9 includes a rinsing process, wet cleaning, and wet etching performed by supplying a processing liquid, a chemical or the like to the substrate, it is not particularly limited.

The processing liquid supplier 1 includes a pipe system 2 for supplying the DIW to the substrate processor 9. Various types of functional units are provided appropriately along the piping to form a flow path of the processing liquid. More specifically, a control valve 211 is interposed in a pipe 21 connected to an external DIW supply source, and a terminal of the pipe 21 is connected to a primary reservoir tank 51. When the control valve 211 is opened in response to a control command from a controller 8 responsible for control over the behavior of the device as a whole, the DIW at room temperature (RT) supplied from the outside flows into the primary reservoir tank 51 through the pipe 21.

In the following, terms “flow direction,” “upstream side,” and “downstream side” are used for defining positions along a flow path of the processing liquid or a cooling medium. Unless specified otherwise, these terms show a flow direction of a liquid at a corresponding position along the flow path, and an upstream side and a downstream side of this flow direction.

A pipe 22 is connected to a lower part of the primary reservoir tank 51. A flowmeter 221, a feed pump 222, a pressure sensor 223, a cooling device 3, a pressure sensor 224, a temperature sensor 225, a control valve 226, a filter 227, and others are connected to the pipe 22. Each of these functional units may be added appropriately, as needed, to a position other than the illustrated position, or some of these functional units may be omitted. As an example, pressure reduction between the upstream side (primary side) and the downstream side (secondary side) with respect to a heat exchanger 35 caused by pressure loss at the heat exchanger 35 can be acquired as data or can be calculated through experiment or simulation conducted previously. Thus, in one configuration, the pressure sensor 224 on the downstream side with respect to the heat exchanger 35 may be omitted.

Each of the flowmeter 221 and flowmeters described later detects the flow rate of a liquid in a flow path. Each of the feed pump 222 and feed pumps described later feeds a liquid supplied from the upstream side of the flow path toward the downstream side. Each of the pressure sensor 224 and pressure sensors described later detects the pressure of the liquid in the flow path. Each of the temperature sensor 225 and temperature sensors described later detects the temperature of the liquid in the flow path.

Each of the flowmeters, the feed pumps, the pressure sensors, and the temperature sensors is communicably connected to the controller 8. An output signal from each of the flowmeters, the pressure sensors, and the temperature sensors is transmitted to the controller 8. Each feed pumps and each control valves described later operate in response to a control command from the controller 8 to regulate the flow of the processing liquid in the flow path. The controller 8 controls the behaviors of movable parts including the feed pumps and the control valves in response to a control program prepared in advance and signals transmitted from sensors including the flowmeters, the pressure sensors, and the temperature sensors.

The cooling device 3 has the function of reducing the temperature of an incoming liquid and outputting the resultant liquid. A final temperature of the processing liquid to be output from the cooling device 3 is not particularly limited. Meanwhile, the final temperature may be set to a temperature lower than room temperature and slightly higher than 0° C as a freezing point of the DIW, for example, and may be set to 5° C, for example. The number of the cooling devices 3 may be one. Meanwhile, in order to reduce the temperature of the processing liquid supplied at room temperature efficiently in shorter time to a target temperature, two or more cooling devices 3 may be connected in series with each other, for example. In order to increase the quantity of the processing liquid to be cooled, two or more cooling devices 3 may be connected in parallel. The cooling device 3 will be described later in detail.

The pipe 22 branches on the downstream side with respect to the filter 227 into a pipe 23 and a pipe 24. A control valve 231 is interposed in the pipe 23, and a terminal of the pipe 23 is connected to the primary reservoir tank 51. Specifically, the pipes 22 and 23 function as a circulation flow path of causing the processing liquid to circulate with respect to the primary reservoir tank 51. As the feed pump 222 for feeding the processing liquid under pressure and the cooling device 3 for cooling the processing liquid are interposed in the pipe 22, the processing liquid circulates through the circulation flow path to maintain the processing liquid in the primary reservoir tank 51 at a predetermined temperature lower than room temperature.

A control valve 241 is interposed in the other pipe 24, and a terminal of the pipe 24 is connected to a secondary reservoir tank 52. The cooled processing liquid passed through the pipe 24 flows into the secondary reservoir tank 52, and the secondary reservoir tank 52 stores the processing liquid therein.

A pipe 25 is connected to a lower part of the secondary reservoir tank 52. A flowmeter 251, a feed pump 252, a cooling device 3, a temperature sensor 253, a control valve 254, and others are connected to the pipe 25. Each of these functional units may be added appropriately, as needed, to a position other than the illustrated position, or some of these functional units may be omitted. A terminal of the pipe 25 is connected to the substrate processor 9. The processing liquid supplied from the secondary reservoir tank 52 is fed under pressure by the feed pump 252 toward the downstream side. The processing liquid finally temperature-regulated by the cooling device 3 is fed to the substrate processor 9 through the control valve 254.

The substrate processor 9 and the secondary reservoir tank 52 are connected to each other by a return pipe 26. A control valve 261 is interposed in the return pipe 26. The processing liquid returning from the substrate processor 9 flows into the secondary reservoir tank 52 through the return pipe 26. In this way, the pipes 25 and 26 form a circulation flow path including the substrate processor 9, and the cooling device 3 is provided along the circulation flow path. This allows the processing liquid stable in temperature to the substrate processor 9.

The pipes and the functional units forming the pipe system 2 are each made of a resin material in a part to contact the processing liquid. As an example, fluorine resin such as perfluoroalkoxy alkane (PFA) resin or polytetra fluoroethylene (PTFE) resin is preferably applicable as a material not to cause release of impurity such as metal ions into the processing liquid.

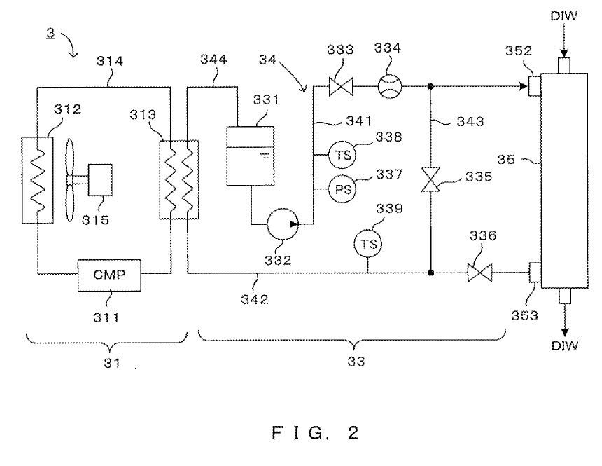

FIG. 2 shows an exemplary configuration of the cooling device. Main structures of the cooling device 3 include a refrigerating circuit 31, a circulating liquid circuit 33, and the heat exchanger 35. A circuit already available as a product can be used as the refrigerating circuit 31. Thus, only a minimum configuration required for explanation of principles is shown in the drawings and the operation thereof will be described simply. Regarding a pressure sensor and a temperature sensor appropriately provided along the flow path as necessary, descriptions of these sensors will also be omitted.

In the cooling device 3, a first cooling medium cooled by the refrigerating circuit 31 is used to cool a second cooling medium to circulate in the circulating liquid circuit 33, and the heat exchanger 35 cools the processing liquid using the second cooling medium thereby cooled. By doing so, the processing liquid is cooled to a desired cooling target temperature. Cooling the processing liquid in this way by the two-stage cooling process using the intervening circulating liquid circuit 33 is intended to eliminate metal to become a contamination source from the pipes and others to be touched by the DIW as the processing liquid, thereby outputting high-purity DIW.

The refrigerating circuit 31 is a so-called chiller, and includes a compressor (compression machine) 311, an air-cooled condenser 312, an evaporator 313, and a pipe 314 connecting these parts to form a circulation flow path. An appropriate cooling medium (first cooling medium) that may be chlorofluorocarbons or a substitute for chlorofluorocarbons, for example, is poured under a high pressure in the circulation flow path. The cooling medium compressed and pressurized by the compressor 311 and the air-cooled condenser 312 is vaporized by the evaporator 313. During the vaporization, heat is drawn from the surrounding to cool a target. Here, a cooling target is the second cooling medium poured in the circulating liquid circuit 33.

A fan motor 315 is arranged near the air-cooled condenser 312, and dissipates heat of condensation generated by the first cooling medium to the outside. While not shown in the drawings, functional units including an expansion valve, a pressure sensor, and a temperature sensor are provided at appropriate positions in the refrigerating circuit 31.

The circulating liquid circuit 33 feeds the cooling medium (second cooling medium) having been cooled by the refrigerating circuit 31 to the heat exchanger 35 in the next stage. For this purpose, the circulating liquid circuit 33 has a configuration where a reservoir tank 331, a feed pump 332, control valves 333, 335, and 336, a flowmeter 334 and others are interposed in a pipe 34. More specifically, the pipe 34 includes a pipe 341 forming connection between a lower part of the reservoir tank 331 and an input port 352 of the heat exchanger 35, a pipe 342 forming connection between an output port 353 of the heat exchanger 35 and the evaporator 313, a pipe 343 forming connection between the pipe 341 and the pipe 342, and a pipe 344 forming connection between the evaporator 313 and the reservoir tank 331.

The feed pump 332, the control valve 333, and the flowmeter 334 are interposed in the pipe 341. The control valve 336 is interposed in the pipe 342. The pipe 343 is provided in such a way as to form connection between the downstream side of the pipe 341 with respect to the flowmeter 334 and the downstream side of the pipe 342 with respect to the control valve 336, and the control valve 335 is provided along a flow path in the pipe 343.

When the feed pump 332 feeds the cooling medium under pressure and the control valve 333 is opened in response to a control command from the controller 8, the cooling medium fed from the reservoir tank 331 is supplied to the heat exchanger 35. By opening the control valve 336, the cooling medium returning from the heat exchanger 35 is allowed to be received in the pipe 342. By opening the control valve 335, the cooling medium fed by the feed pump 332 is allowed to flow at least partially or entirely into the pipe 342 while bypassing the heat exchanger 35.

The cooling medium having flowed into the pipe 342 flows back into the reservoir tank 331 through the evaporator 313 and the pipe 344. In this way, a flow path for causing the cooling medium (second cooling medium) to circulate from the reservoir tank 331 through the evaporator 313 is formed in the circulating liquid circuit 33, and the second cooling medium cooled by the evaporator 313 circulates in the circulating liquid circuit 33. As a result, the temperature of the circulating cooling medium is stabilized.

A pressure sensor 337 and a temperature sensor 338 are provided on the downstream side of the pipe 341 with respect to the feed pump 332. An additional temperature sensor 339 is provided on the downstream side of the pipe 342 with respect to a point of merging with the pipe 343. The controller 8 controls the feed pump 332 and the control valves 333, 335 and 336 on the basis of output signals from these sensors, thereby feeding the cooling medium at a predetermined temperature and a predetermined flow rate into the heat exchanger 35.

A liquid to be used as the second cooling medium is a liquid coolable to a lower temperature than a final cooling target temperature of the processing liquid (in this example, 5°C and this temperature will be called a “final target temperature”) without being coagulated by freezing. For example, ethylene glycol (EG) having a melting point of minus 13°C or an aqueous solution thereof is preferably available. Regarding the temperature of the second cooling medium, the second cooling medium is maintained at a lower temperature than the target temperature of the processing liquid to be output from the cooling device 3.

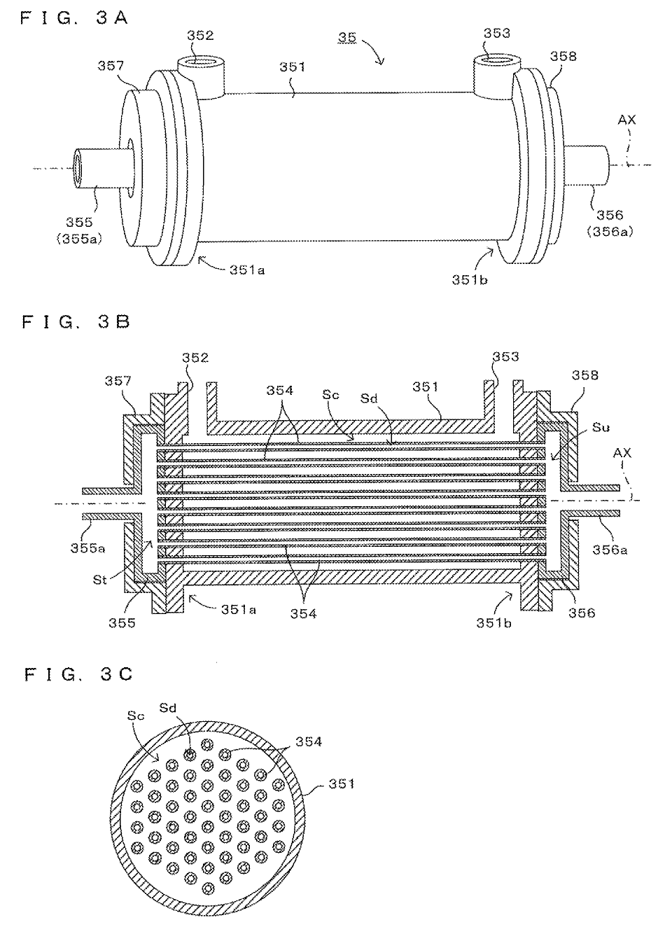

FIGS. 3A - 3C show an exemplary configuration of the heat exchanger. More specifically, FIG. 3A shows the appearance of the heat exchanger 35. In FIG. 3A, a dash-dot line shows a virtual center axis AX of the heat exchanger 35. FIG. 3B is a longitudinal sectional view showing a section of the heat exchanger 35 along the center axis AX. FIG. 3C is a cross sectional view showing a section perpendicular to the center axis AX.

The heat exchanger 35 includes a housing 351 having a substantially circular columnar outer shape with a hollow interior extending along the center axis AX, in other words, having a circular cylindrical shape with closed opposite ends. The housing 351 has a side surface where the input port 352 is provided at a position close to one edge 351a of the housing 351, and the output port 353 is provided at a position close to the other edge 351b of the housing 351 opposite to the one edge 351a. The cooling medium fed from the circulating liquid circuit 33 flows through the input port 352 into an internal space defined by an inner wall of the housing 351, and flows out through the output port 353. The cooling medium having flowed into the internal space of the housing 351 fills an external side of an inner pipe inserted in and passed through the internal space and used for causing the DIW to flow therein. In the internal space of the housing 351, a space except the inner pipe and except a space in the inner pipe is called a current space Sc. The cooling medium supplied from the circulating liquid circuit 33 to the heat exchanger 35 flows in the current space Sc.

The housing 351 includes a plurality of inner pipes 354 inserted in and passed through the housing 351 and penetrating the current space Sc from the one edge 351a to the other edge 351b of the housing 351. On the side of the one edge 351a, the inner pipe 354 is terminated by a terminal member 355 and an internal space Sd of the inner pipe 354 communicates with an internal space St of the terminal member 355. Likewise, on the side of the other edge 351b, the inner pipe 354 is terminated by a terminal member 356 and the internal space Sd of the inner pipe 354 communicates with an internal space Su of the terminal member 356. As a result, the respective internal spaces St and Su of the terminal members 355 and 356 communicate with each other via the internal space Sd of the inner pipe 354.

An input port 355a for receiving the DIW to be cooled is provided at an end of the terminal member 355. An output port 356a for feeding the DIW is provided at an end of the terminal member 356. The input port 355a connects to one end of each of the inner pipes 354, and the other end of each inner pipe 354 connects to the output port 356a. Thus, the inner pipes 354 have a parallel relationship with each other in terms of a flow path of the DIW. The DIW having flowed into the internal space St from the input port 355a branches into flows to enter the inner pipes 354, passes through the internal space Sd of each inner pipe 354 to flow out into the internal space Su, and is then fed through the output port 356a toward the downstream side with respect to the heat exchanger 35. Specifically, the terminal member 355 and the inner pipes 354 function as a manifold for branching the DIW, and the inner pipes 354 and the terminal member 356 function as a manifold for merging the flows of the DIW.

In the following, if the input port 355a and the input port 352 are required to be distinguished from each other, they will be called an “input port 355a for DIW” and an “input port 352 for cooling medium.” Likewise, if the output port 356a and the output port 353 are required to be distinguished from each other, they will be called an “output port 356a for DIW” and an “output port 353 for cooling medium.”

The inner pipe 354 and the terminal members 355 and 356 are made of resin materials not to cause release of impurity such as metal ions. Like the other pipes, the inner pipe 354 and the terminal members 355 and 356 are formed by using a material that is preferably a fluorine resin material such as PFA resin, for example. As an example, a PFA tube is available as the inner pipe 354. Regarding the terminal members 355 and 356 each required to be processed into a complicated shape, PTFE resin is available in addition to PFA resin. The terminal members 355 and 356 can be formed into the same shape.

The terminal members 355 and 356 are fixed to the housing 351 by cover members 357 and 358 respectively. Specifically, the terminal member 355 is mounted on the one edge 351a of the housing 351 in such a way as to be interposed between the one edge 351a of the housing 351 and the cover member 357. Likewise, the terminal member 356 is mounted on the other edge 351b of the housing 351 in such a way as to be interposed between the other edge 351b of the housing 351 and the cover member 358. The cover members 357 and 358 can be formed into the same shape.

The housing 351 and the cover members 357 and 358 are each made of metal such as stainless steel, for example, and are coupled to each other with coupling members such as bolts not shown in the drawings. As will be described later, while each of the cooling medium and the DIW is supplied to the heat exchanger 35 in a pressurized state, forming the housing 351 using solid metal provides resistance to such a pressure. The resin terminal members 355 and 356 themselves do not have high resistances to such a pressure. However, reinforcing the terminal members 355 and 356 from outside using the cover members 357 and 358 allows the terminal members 355 and 356 to be resistant to such a pressure.

The current space Sc and the internal space Sd of the inner pipe 354 are separated from each other by a pipe wall of the inner pipe 354, and the cooling medium flowing in the current space Sc and the DIW flowing in the internal space Sd are separated from each other. An outer surface of the pipe wall touches the cooling medium at a low temperature. Thus, the DIW is cooled through heat exchange with the cooling medium across the pipe wall, and is output from the output port 356a at a lower temperature than the temperature of the DIW during input from the input port 355a. As the inner pipes 354 are inserted in and passed through the interior of the housing 351, the DIW is cooled at high efficiency. Here, the cooling medium and the DIW flow in the same direction (in FIG. 3A, toward the right) in the heat exchanger 35. Meanwhile, the flow direction of the cooling medium and the flow direction of the DIW may be reversed by switching the input and output of the cooling medium, for example.

If the cooling devices 3 are connected in multiple stages, a cooling target temperature at each cooling device 3 is not required to be the final target temperature. Specifically, in a configuration of bringing the DIW to the final target temperature stepwise using the cooling devices 3 in multiple stages, a temperature reduction required to be attained in each cooling device 3 can be smaller. In this case, each of the temperature of the DIW to be input and the temperature of the DIW to be output differs between the cooling devices 3, so that the cooling devices 3 are not always required to be the same in terms of respective configurations and specifications.

In the above configuration, the cooling medium flowing in the current space Sc and the DIW flowing in the internal space Sd of the inner pipe 354 do not come into contact with each other. The DIW is passed through inside the resin pipe. As a result, mixture of impurity such as a component in the cooling medium or metal ions into the DIW is avoided. However, if a high pressure is applied to the inner pipe 354 that is a resin pipe not always having high mechanical strength to cause a crack or the like in the inner pipe 354, such impurity might be mixed into the DIW. This is prevented by taking countermeasures described below.

In this embodiment, the above problem is handled by regulating the pressure of the cooling medium and that of the DIW to be supplied to the heat exchanger 35. Specifically, if a crack occurs in the pipe wall of the inner pipe 354, leaching of a liquid might be caused by a pressure difference between liquids existing across the pipe wall. If the pressure of the cooling medium is higher than the pressure of the DIW, the cooling medium leaches out from the current space Sc toward the internal space Sd of the inner pipe 354. This means mixture of the cooling medium into the DIW flowing in the inner pipe 354.

On the other hand, if the pressure of the DIW is higher than the pressure of the cooling medium, mixture of the cooling medium into the DIW flowing in the inner pipe 354 is avoided while the DIW might leach out into the current space Sc to be mixed into the cooling medium. In this embodiment, control is performed over the cooling medium and/or the DIW in terms of pressure in the heat exchanger 35 in such a way as to bring the DIW to a higher pressure between the cooling medium and the DIW existing across the pipe wall of the inner pipe 354 in the current space Sc.

In the configuration of this embodiment shown in FIGS. 1 and 2, it is possible to realize the above-described pressure control by causing the controller 8 to control control subjects including the feed pumps 222 and 332 and the control valves 226, 333, 335 and 336 on the basis of detection signals from the pressure sensors 223, 224, 338 and others provided along the flow paths.

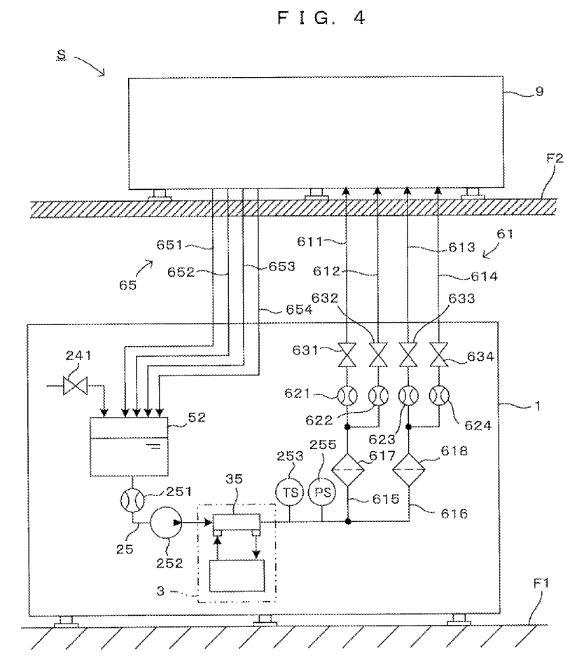

FIG. 4 shows layout of the substrate processing system and an example of an interconnecting pipe. The substrate processor 9 is required to be placed in a highly atmosphere-controlled environment. However, this is not always true of the processing liquid supplier 1. On the contrary, locating these units at separate positions is a way generally employed in order to prevent dust and others generated in the processing liquid supplier 1 from becoming a contamination source. As shown in FIG. 4, for example, the processing liquid supplier 1 and the substrate processor 9 may be arranged one above the other by installing the processing liquid supplier 1 on a floor F1 and installing the substrate processor 9 on a different floor F2.

In this case, in order to supply the processing liquid, the processing liquid supplier 1 and the substrate processor 9 are connected to each other through an interconnecting line having a comparatively large flow path length. In FIG. 1, for the explanation in outline, a feed pipe for feeding the processing liquid from the processing liquid supplier 1 to the substrate processor 9 is shown by the single pipe 25, and a return pipe for causing the processing liquid to flow from the substrate processor 9 back into the processing liquid supplier 1 is shown by the single pipe 26. In an actual case, however, the configuration shown in FIG. 4 is adopted.

Specifically, a feed pipe 61 for supplying the processing liquid from the processing liquid supplier 1 to the substrate processor 9 includes four pipes 611, 612, 613, and 614. More specifically, the pipe 25 in the processing liquid supplier 1 branches into two pipes 615 and 616, and the pipe 615 further branches into the two pipes 611 and 612. The pipe 616 branches into the two pipes 613 and 614. Filters 617 and 618 are interposed in the pipes 615 and 616 respectively.

The pipe 611 is provided with a flowmeter 621 and a control valve 631 arranged in this order in a flow direction of the processing liquid. Likewise, the pipe 612 is provided with a flowmeter 622 and a control valve 632, the pipe 613 is provided with a flowmeter 623 and a control valve 633, and the pipe 614 is provided with a flowmeter 624 and a control valve 634. These structures are used to control the quantity of the processing liquid to flow into the substrate processor 9 through each of the pipes 611 to 614. As appropriate, the pipe 25 is additionally provided with a pressure sensor 255 for detecting the pressure of the processing liquid to be fed.

Here, on the assumption that the substrate processor 9 includes four substrate processing units (not shown in the drawings), the feed pipe 61 is composed of the four pipes 611 to 614. This allows all the substrate processing units to perform substrate process independently of each other using the processing liquid supplied from the processing liquid supplier 1. However, the substrate processing units belonging to the substrate processor 9 is not limited to this. The number of pipes belonging to the feed pipes 61 becomes free from limitation correspondingly.

The return pipe 65 for causing the processing liquid to flow from the substrate processor 9 back into the processing liquid supplier 1 also includes four pipes 651, 652, 653, and 654 corresponding to the respective substrate processing units. Respective terminals of the pipes 651 to 654 are connected to the secondary reservoir tank 52 to cause the processing liquid from the substrate processor 9 to flow back into the secondary reservoir tank 52. Specifically, the processing liquid at a low temperature fed from the secondary reservoir tank 52 is supplied from the pipe 25 to the substrate processor 9 through the feed pipe 61, and flows back from the substrate processor 9 into the secondary reservoir tank 52 through the return pipe 65. In this way, the processing liquid is caused to circulate.

As described above, the feed pipe 61 and the return pipe 65 function as the interconnecting pipe forming connection between the processing liquid supplier 1 and the substrate processor 9 located at positions separate from each other. In this example, the interconnecting pipe spans floors in a factory, and has a comparatively large flow path length that may be equal to or greater than 20 meters, for example. The DIW as the processing liquid is temperature-regulated at a low temperature (5°C), and the processing liquid at such a low temperature flows through the interconnecting pipe.

In this case, two problems might occur. A first problem is that the temperature of the processing liquid increases gradually in response to flow thereof. A second problem is that dew condensation occurs on a surface of the interconnecting pipe or on a periphery thereof. To settle these problems, the interconnecting pipe is desirably configured to have high heat-insulating performance. In this embodiment, in response to these problems, an interconnecting pipe having a double pipe configuration is used as described below. While the configuration of the pipe 611 will be described as an example, a similar configuration is also applied to the other pipes forming the feed pipe 61 and the return pipe 65.

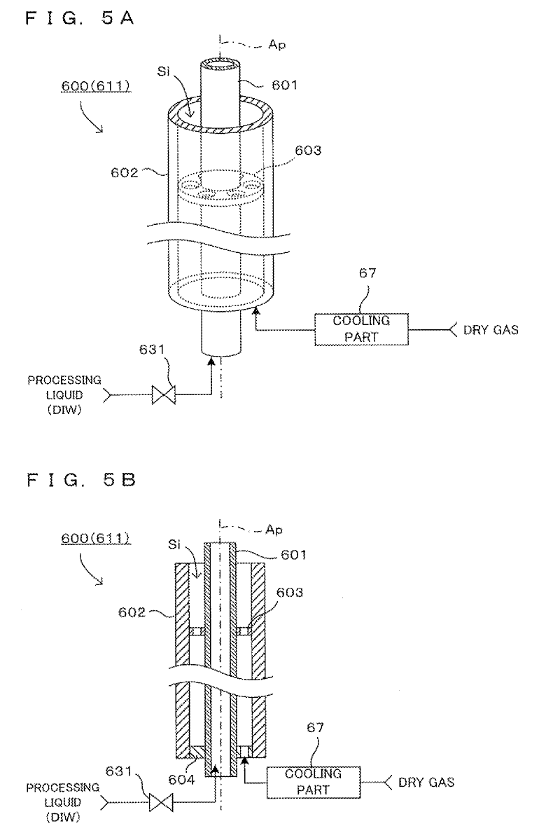

FIGS. 5A and 5B show the configuration of a pipe applicable as the feed pipe. More specifically, FIG. 5A shows the configuration of a double pipe 600 in outline used as the feed pipe, and FIG. 5B is a sectional view taken along a pipe axis direction of the pipe.

As shown in FIG. 5A, as the pipe 611, the double pipe 600 is applicable that has a configuration where a processing liquid pipe (hereinafter denoted as an “inner pipe 601”) for causing the processing liquid (DIW) to flow therein is inserted in an exterior pipe (hereinafter denoted as an “outer pipe 602”). The inner pipe 601 is to receive the processing liquid to flow therein through the control valve 631, and is a tube made of a resin material (fluorine resin material such as PFA, for example) not to cause release of impurity to become a contamination source. On the other hand, the outer pipe 602 is not to come into direct contact with the processing liquid, and can be made of a material appropriately selectable. The outer pipe 602 is required to have high heat-insulating performance, and in this regard, is desirably a resin pipe having lower heat conductivity than a metal pipe. In order to enhance the heat-insulating performance further, a (closed-cell) foam resin material is applicable. As an example, the outer pipe 602 may be prepared by combining several types of materials like a pipe including a stack of a metal layer for ensuring mechanical strength and a resin layer for enhancing heat-insulating performance.

In particular, if at least one of the inner pipe 601 and the outer pipe 602 is a soft pipe having flexibility, these pipes may come into contact with each other in a place of a path along which the pipes are routed long. Such a place of contact acts as a heat bridge to cause the temperature increase and dew condensation described above. In response to this, a spacer 603 is provided in an internal space Si of the outer pipe 602.

The spacer 603 is provided in a clearance between the inner pipe 601 and the outer pipe 602 to support the inner pipe 601 coaxially with the outer pipe 602. This prevents contact between the inner pipe 601 and the outer pipe 602. While only one spacer 603 is illustrated, two or more spacers 603 are arranged separately at a predetermined interval in a direction along a pipe axis Ap of the inner pipe 601. By doing so, it becomes possible to maintain the coaxial structure along the entire feed pipe. The configuration of the spacer 603 will be described later in more detail.

To control an atmosphere in the internal space Si of the outer pipe 602, dry gas from an appropriate supply source is supplied through a cooling part 67. More specifically, as shown in FIG. 5B, an end of the outer pipe 602 is terminated by a seal member 604, and the dry gas cooled by the cooling part 67 is introduced into the internal space Si through the seal member 604. Filling a periphery of the inner pipe 601 with the dry gas in this way prevents the occurrence of dew condensation on an outer peripheral surface of the inner pipe 601. Note that, the gas to be introduced is desired to be dry gas not containing moisture, and is also desired to have a dew-point temperature lower than the temperature of the processing liquid. As an example, clean dry air (CDA) or nitrogen gas is favorably applicable.

Gas not containing oxygen such as nitrogen gas or inert gas is effective, particularly if the inner pipe 601 is made of fluorine resin. Reason for this is that, fluorine resin has the characteristic of causing oxygen even slightly to pass therethrough, so that it is exposed to the risk of mixture of oxygen into the processing liquid. This problem can be settled by performing atmosphere control by which the periphery of the inner pipe 601 is covered by a layer of the gas not containing oxygen.

By cooling the dry gas using the cooling part 67 to be introduced into the internal space Si, it becomes possible to maintain the internal space Si in a low-temperature environment, thereby suppressing temperature increase of the processing liquid. From the viewpoint of preventing temperature increase, the internal space Si is preferably cooled to a temperature substantially equal to the temperature of the processing liquid. On the other hand, a low temperature in the internal space Si increases a likelihood of the occurrence of dew condensation on an outer peripheral surface of the outer pipe 602. This problem may be settled by enhancing the heat-insulating performance of the outer pipe 602 through selection of a material and the thickness of a pipe wall of the outer pipe 602, or by increasing a temperature in the internal space Si to a degree not to cause dew condensation. For example, the temperature of the dry gas to be introduced may be set to a temperature higher than the temperature of the processing liquid and lower than room temperature.

Like the processing liquid, the dry gas also increases in temperature in response to flow thereof. Thus, in order to fulfill effect achieved by introducing the cooled dry gas, the processing liquid and the dry gas preferably flow in the same direction. In this example, the processing liquid flows upward in the inner pipe 601. Thus, the dry gas is supplied into the internal space Si from a lower end of the outer pipe 602. In order for the introduced dry gas to flow smoothly in the internal space Si, the spacer 603 is configured to form a gas flow path for generating a flow in a direction in which the pipe axis Ap of the inner pipe 601 extends (this direction will be called a “pipe axis direction”), which is, specifically, a top-bottom direction in the drawing.

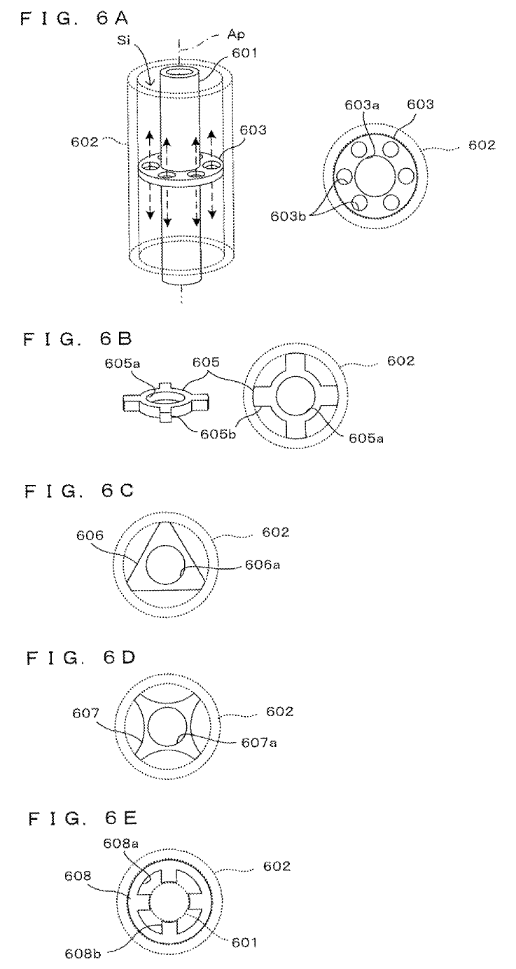

FIGS. 6A - 6E show the configuration of the spacer. In FIG. 6A, to make the configuration of the spacer 603 visible more easily, the outer pipe 602 is shown by dotted lines. As shown in the left view and the right view of FIG. 6A, the spacer 603 has a circular disk shape with an outer diameter substantially equal to the inner diameter of the outer pipe 602. The spacer 603 is provided with a through hole 603a formed in a center area thereof and having a diameter substantially equal to the outer diameter of the inner pipe 601. The inner pipe 601 is inserted in the through hole 603a. By doing so, the spacer 603 is mounted like a flange on the outer peripheral surface of the inner pipe 601.

The spacer 603 is made of a material having low heat conductivity and may be made of a resin material, for example. The thickness of the spacer 603 is desirably as small as possible within a range in which necessary and sufficient mechanical strength is obtained. This makes it possible to prevent the spacer 603 from acting as a heat bridge between the inner pipe 601 and the outer pipe 602. The spacer 603 having such characteristics can be prepared by foam molding using a resin material, for example.

The spacer 603 is provided with at least one through hole 603b in addition to the through hole 603a. In this example, six through holes 603b are provided in such a way as to surround the through hole 603a. Inside the outer pipe 602, parts of the internal space Si resulting from partitioning in the pipe axis direction by the spacer 603 communicate with each other through the through holes 603b. As a result, the through holes 603b function as gas flow paths in the internal space Si as indicated by dashed arrows in FIG. 6A to allow gas to flow in the pipe axis direction through the spacer 603. Thus, the dry gas supplied into the internal space Si from the end of the outer pipe 602 passes through the spacer 603 provided at a corresponding position to extend over the internal space Si entirely. As a result, the effect by the dry gas is fulfilled along the entire interconnecting pipe.

The through hole 603b even allows liquid to pass therethrough. Thus, even on the occurrence of leakage of the processing liquid from the inner pipe 601, the leaking processing liquid moves down through the internal space Si. In this way, the liquid component leaking in this way can be collected in the processing liquid supplier 1 and is prevented from flowing out to the outside. The dry gas flows around the inner pipe 601. Thus, if the processing liquid leaks to a tiny quantity, the leaking processing liquid is vaporized and discharged, and does not stay in the internal space Si.

If the spacer 603 is made of a porous material, particularly a resin material having an open-cell structure, the spacer 603 allows gas and liquid to pass through the interiors of interconnected cells. For this reason, it is not always necessary to provide a through hole corresponding to the through hole 603b to become a gas flow path in the case described above. That is, if the spacer is formed using a porous material, the spacer is simply required to be provided with a through hole for insertion of the inner pipe 601. The function as a spacer can also be fulfilled by simply winding a porous resin base material having a shape like a sheet or a rod, for example, around the outer peripheral surface of the inner pipe 601. In this case, the hardness of the base material is required to be selected in such a way that even bending the pipe still prevents the inner pipe 601 and the outer pipe 602 from coming close to or coming into contact with each other.

FIGS. 6B - 6E show other exemplary shapes of the spacer. A spacer 605 shown in FIG. 6B has a shape corresponding to a configuration determined by partially cutting out an outer periphery of a ring-like member provided with a through hole 605a formed at the center and used for insertion of the inner pipe 601. In other words, the spacer 605 has a shape determined by partially projecting the outer periphery of the circular ring having an outer diameter smaller than the inner diameter of the outer pipe 602. In this configuration, a space formed between cutouts (or projections) 605b and an inner wall surface of the outer pipe 602 functions as a gas flow path to achieve effect comparable to that described above. The number of the projections is determined freely.

A spacer 606 shown in FIG. 6C has a triangular outer peripheral shape with rounded vertexes. A through hole 606a for insertion of the inner pipe 601 is formed in a center area of the spacer 606. A spacer 607 shown in FIG. 6D has an outer shape based on a square having rounded vertexes and having each side given a curvature. In each of these configurations, a space formed between an outer peripheral surface of the spacer 606, 607 and the inner wall surface of the outer pipe 602 also functions as a gas flow path to achieve effect comparable to that described above. Note that a shape to become a base for the spacer is not limited to those shown in the drawings but an arbitrary polygonal shape is applicable. Such a shape is not required to be a regular polygonal shape.

Although the shapes of the spacers shown in FIGS. 6B - 6D are different in the respective shapes of the outer peripheral surfaces, they follow the same supporting principle in terms of providing a part projecting outward partially from the center area for supporting the inner pipe 601, and bringing the projecting part into contact with the inner wall surface of the outer pipe 602, thereby defining the position of the inner pipe 601 in the internal space Si while ensuring a gas flow path in a gap from the inner wall surface of the outer pipe 602.

A spacer 608 shown in FIG. 6E has a shape determined by providing a plurality of projections 608b projecting toward a center area partially from a circular ring having an outer diameter substantially equal to the inner diameter of the outer pipe 602 and provided with a through hole 608a formed in the center area and larger than the outer diameter of the inner pipe 601. In this configuration, while an outer peripheral surface of the spacer 608 is entirely in contact with the inner wall surface of the outer pipe 602, tips of the projections 608b are in contact with the outer peripheral surface of the inner pipe 601 to define the position of the inner pipe 601. In this case, a gap between the projections 608b functions as a gas flow path.

As described previously, the feed pipe 61 for feeding the processing liquid from the processing liquid supplier 1 to the substrate processor 9 includes the four pipes 611 to 614 responsive to the number of the processing units provided in the substrate processor 9. A configuration similar to the above double pipe 600 is applicable to each of these pipes 611 to 614. Meanwhile, if the temperatures of the processing liquid to be passed are equal to each other or not differing from each other largely like those of the processing liquid to be passed through the pipes 611 to 614, as will be illustrated next, the pipes 611 to 614 may each be handled as an inner pipe and may be configured to be covered collectively by an outer pipe.

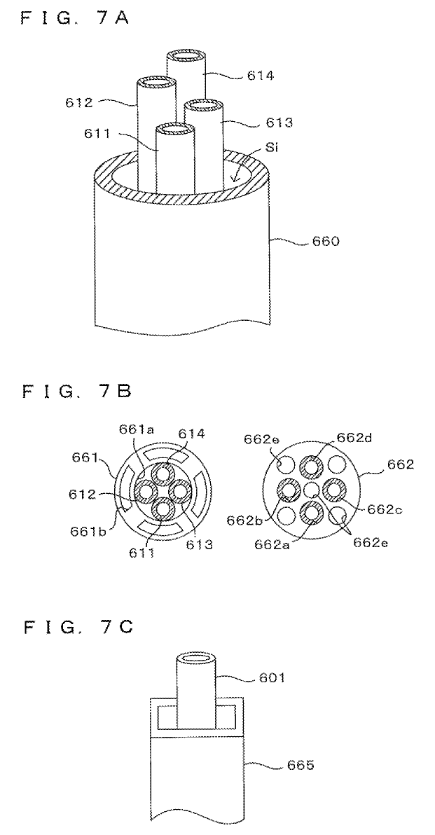

FIGS. 7A - 7C show a modification of the feed pipe. As shown in FIG. 7A, regarding the pipes 611 to 614 independent of each other and through which the processing liquid is to be passed at temperatures not differing from each other, these pipes may be arranged inside an outer pipe 660 surrounding peripheries thereof collectively. This achieves reduction in a space occupied by the feed pipe 61 as a whole. Gathering the pipes with small temperature differences therebetween makes it possible to reduce dissipation of heat energy.

In this case, the pipes 611 to 614 may be in contact with each other, or may be close to each other but not in contact with each other. FIG. 7B shows exemplary shapes of spacers to realize these states. A spacer 661 shown in the left view of FIG. 7B has a ring-like shape including a through hole 661a for insertion of the pipes 611 to 614 collectively, and a through hole 661b to function as a gas flow path.

In this configuration, there is no function for separating the pipes 611 to 614 actively from each other. Thus, the pipes 611 to 614 are supported while coming into contact with each other partially and separating from each other partially in the pipe axis direction. The temperatures of the processing liquid to be passed through the pipes 611 to 614 are equal to each other and surface temperatures of the pipes 611 to 614 are also considered to be substantially equal to each other. Thus, contact between the pipes with no temperature difference therebetween does not become a cause for a heat bridge.

On the other hand, a spacer 662 shown in the right view of FIG. 7B is provided with through holes 662a, 662b, 662c, and 662d for insertion of the pipes 611, 612, 613, and 614 individually, and through holes 662e to become gas flow paths are provided appropriately in a gap between these through holes. In this configuration, the pipes 611 to 614 are supported while being separated from each other inside the outer pipe 660.

Each of the above configurations prevents any of the pipes to become a heat bridge resulting from coming close to or coming into contact with the outer pipe 660. Moreover, a gas flow path is ensured to impose no hindrance to flow of the dry gas. Regarding the shape of the spacer, every type of shape shown in FIG. 6A to 6E is applicable.

Note that, if there is a significant difference between the temperatures of the processing liquid to be passed through a plurality of pipes, it is at least required to avoid contact between these pipes. Thus, it is at least preferable to use a spacer having a configuration such as the spacer 662 shown in the right view of FIG. 7B, or it is preferable to provide double pipes themselves individually.

A PFA tube already prepared is favorably available as the inner pipe 601 for causing the processing liquid to flow therein. However, this in turn imposes a certain degree of limitation on the sectional shape thereof. By contrast, regarding the outer pipe 602, higher degrees of freedom are given in selecting a material and a shape thereof. That is, the shape of the outer pipe is not limited to the above circular cylindrical shape but is determined freely. As shown in FIG. 7C, for example, a pipe 665 having a rectangular section may be used as an outer pipe. In this case, a spacer having a shape conforming to an inner wall surface of the outer pipe may be used.

Description will be continued by referring back to FIG. 5. As described above, the shape of the spacer, that of the outer pipe, and the number of the inner pipes may be changed, as appropriate. As long as the spacer 603 is provided between the inner pipe 601 and the outer pipe 602 and defines the clearance between the pipes, the spacer 603 is not always required to be fixed to either of the pipes. For this reason, the spacer 603 is movable in the pipe axis direction in the internal space Si. Meanwhile, in order to maintain the clearance along the entire pipes, it is required to arrange a plurality of the spacers 603 discretely, if possible, at a constant interval.

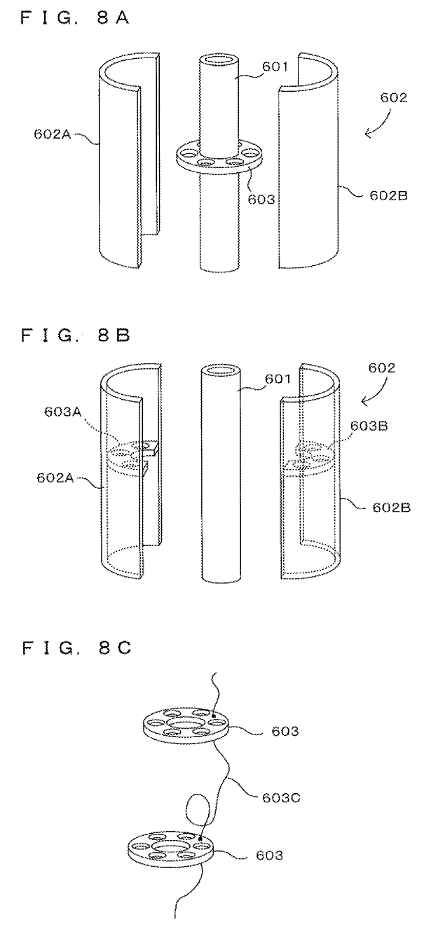

Thus, in manufacturing the double pipe 600, the spacers 603 are required to be arranged at an appropriate interval, more preferably, at a constant interval in the pipe axis direction, and the positions thereof are required to be unchanged. An exemplary configuration of the double pipe 600 for attaining such a structure will be described by referring to FIGS. 8A - 8C.

FIGS. 8A -8C show exemplary configurations of the double pipe for the spacer. As shown in FIG. 8A, the outer pipe 602 can be manufactured by being divided into two semicircular cylindrical members 602A an 602B, for example. The spacer 603 is formed using an elastic material, and the through hole 603a at the center is configured to have an inner diameter slightly smaller than the outer diameter of the inner pipe 601. By inserting the inner pipe 601 into the resultant spacer 603, the spacer 603 is temporarily fixed by its elasticity to the inner pipe 601. The temporary fixation mentioned herein means that, while the spacer 603 is not fixed to the inner pipe 601, a positional relationship therebetween is defined in a state of making displacement in the pipe axis direction unlikely to occur by means of frictional force.

In this state, the two members 602A and 602B are combined together in such a way as to interpose the inner pipe 601 therebetween to form the outer pipe 602. By doing so, the spacer 603 is interposed between the inner pipe 601 and the outer pipe 602 while being maintained at an original position. As a result, it is possible to form the double pipe 600 where the spacer 603 is arranged at an intended position. While not shown in the drawings, an appropriate engagement mechanism or a fastening mechanism is available for connection between the members 602A and 602B.

As shown in FIG. 8B, the spacer 603 may be manufactured by being divided into two members 603A and 603B, these members may be mounted in advance on the corresponding two members 602A and 602B to form the outer pipe 602, and the outer pipe 602 may be assembled in such a way as to interpose the inner pipe 601 therein. Unless disassembling is required subsequently, the outer pipe 602 may be fixed permanently through adhesion or welding, for example.

If the spacer 603 is movable freely in the pipe axis direction between the inner pipe 601 and the outer pipe 602, it is still possible to arrange a plurality of the spacers 603 at a constant interval. As shown in FIG. 8C, for example, these spacers 603 are coupled while separated from each other at a constant interval in advance using a coupling member 603C such as a thread or a wire. By passing these spacers 603 sequentially through the inner pipe 601, the spacers 603 become functional to restrict displacement relative to each other in the pipe axis direction in the internal space Si. As a result, an interval between the spacers 603 is necessarily maintained constantly inside the double pipe 600. In this case, the outer pipe 602 may be a pipe formed in advance into a pipe shape.

The double pipe 600 described herein is further applicable in the same way as the return pipe 65 for causing the processing liquid to flow from the substrate processor 9 back into the processing liquid supplier 1. Compared to the feed pipe 61, the return pipe 65 is subjected to a relaxed requirement for the temperature of the processing liquid, so that it has a higher degree of design freedom. Meanwhile, as the temperature of the processing liquid is not always the same between the feed pipe and the return pipe, it is preferable to avoid housing the feed pipe and the return pipe into the same outer pipe.

As described above, in this embodiment, the processing liquid supplier 1 configured to generate and output the cooled DIW as the processing liquid, and the substrate processor 9 configured to perform substrate process using the processing liquid are arranged separately from each other. These are connected to each other through the interconnecting pipe for causing the processing liquid to flow therein. Configuring the interconnecting pipe as the double pipe encourages settlement of the problem of temperature increase of the processing liquid and dew condensation to be caused by carrying the processing liquid at a low temperature over a long distance through the interconnecting pipe.

Even in the case of using the double pipe, the presence of contact between the inner pipe and the outer pipe still causes a heat bridge at a place of the contact, failing to provide settlement of the above problem. The double pipe 600 of this embodiment includes the spacers 603 provided at a constant interval between the inner pipe 601 as the processing liquid pipe and the outer pipe 602 as the exterior pipe, thereby avoiding contact between the inner pipe 601 and the outer pipe 602. This prevents the inner pipe 601 and the outer pipe 602 from functioning as a heat bridge due to contact therebetween.

The spacer 603 is configured to allow gas to flow in the pipe axis direction of the inner pipe 601. This allows gas that may be dry gas, for example, to flow in the clearance space between the inner pipe 601 and the outer pipe 602, making it possible to control an atmosphere around the inner pipe 601 properly. Further, even if dew condensation occurs on the outer peripheral surface of the inner pipe 601 or even if the processing liquid leaks, such dew or the leaking processing liquid can be collected without flowing out to the outside.

As described above, in the above embodiment, the substrate processing system S corresponds to a “substrate processing apparatus” of the present invention, and the processing liquid supplier 1 and the substrate processor 9 function as a “processing liquid supplier” and a “substrate processor” of the present invention respectively. The feed pipe 61 corresponds to an “interconnecting pipe” of the present invention in a narrow sense. Meanwhile, in a wider sense, the return pipe 65 can also be said to correspond to the “interconnecting pipe.”

The pipes including the pipe 611 forming the interconnecting pipe are each considered as the double pipe 600. Regarding the double pipe 600, the inner pipe 601 corresponds to a “processing liquid pipe” of the present invention and the outer pipe 602 corresponds to an “exterior pipe” of the present invention. Members including the spacer 603 function as a “spacer member” of the present invention. To be more specific, regarding the spacer 603, for example, the through hole 603a for insertion of the inner pipe 601 corresponds to a “through hole” of the present invention, and the through hole 603b to become a gas flow path functions as a “gas passing hole” and a “flow path forming part” of the present invention. Each of the respective spacers such as the spacer 605 according to the corresponding modifications is provided with structures corresponding to the “through hole” and the “flow path forming part” of the present invention. The cooling part 67 and a supply source not shown in the drawings function as a “gas supplier” of the present invention.

Note that the invention is not limited to the above embodiment, and various changes other than the aforementioned ones can be made without departing from the gist of the invention. For example, in the above embodiment, cooled dry gas is passed between the inner pipe 601 and the outer pipe 602 of the double pipe 600. This suppresses temperature increase of the processing liquid to be carried over a long distance. However, a degree of temperature increase is smaller with a shorter flow path length, for example. Thus, in this case, the dry gas may be supplied without being cooled. The dry gas has the effect of preventing the occurrence of dew condensation on the outer peripheral surface of the inner pipe 601. Meanwhile, the absence of leakage to the outside of the pipe or the absence of stay inside the pipe can be said to cause no effect on the outside. Thus, instead of using low dew-point dry gas, other options can be taken such as using a different type of gas or stopping flow of gas itself.

The configuration of the cooling part 67 to cool gas is not particular limited but a cooling part based on arbitrary cooling principles is applicable. As an example, an available cooling part can be selected from a chiller, a configuration using the Peltier effect, a configuration using a vortex tube, and others.

In the above embodiment, the processing liquid to be supplied through the interconnecting pipe is the cooled DIW. However, the composition or temperature of the processing liquid is not limited to this but is determined freely. If fluorine resin pipes are used in parts of the above pipe system 2 to come into direct contact with the processing liquid, for example, these pipes are further given resistance to a corrosive chemical. For this reason, the present invention is further applicable to the purpose of causing such a chemical to flow. In particular, in response to the need to cause a liquid to flow cooled to a temperature around 0° C or lower than 0° C, the effect of preventing dew condensation by the present invention is achieved notably. While the problem of dew condensation does not occur if the processing liquid is a warmed liquid, a problem still remains in terms of causing gradual decrease in the temperature of the processing liquid to flow. The present invention further works effectively against such a problem.

As the specific embodiment has been illustrated and described above, in the substrate processing apparatus according to the present invention, the spacer member may be provided with a through hole for insertion of the processing liquid pipe, for example. In this configuration, the processing liquid pipe is supported while being inserted in the through hole inside the exterior pipe. Thus, a clearance from the exterior pipe is ensured stably. As a result, contact between the processing liquid pipe and the exterior pipe is prevented more reliably.

For example, the spacer member may be provided with a gas passing hole penetrating the spacer member in the pipe axis direction and functioning as the gas flow path. In this configuration, by causing gas to flow through the gas passing hole, it becomes possible to control an atmosphere properly around the processing liquid pipe.

For example, an outer periphery of the spacer member may be configured to project outward partially to come into contact with the inner wall surface of the exterior pipe. In this case, a gap between a part of the outer periphery of the spacer member not in contact with the inner wall surface of the exterior pipe and the inner wall surface is available as the gas flow path.

For example, in a configuration where an inner periphery of the through hole for insertion of the processing liquid pipe partially projects inward to come into contact with the outer wall surface of the processing liquid pipe, a gap between a part of the inner periphery of the through hole not in contact with the outer wall surface of the processing liquid pipe and the outer wall surface is available as the gas flow path.

For example, the spacer member may be made of a resin material having an open-cell structure. This configuration allows gas to flow through the porous spacer member having an open-cell structure, and such a configuration itself fulfills the function as the flow path forming part.

For example, a plurality of the spacer members may be arranged at an interval in the pipe axis direction. In this configuration, even if the interconnecting pipe extends long, it is still possible to prevent contact between the processing liquid pipe and the exterior part at every part of the interconnecting pipe.

Further, in the substrate processing apparatus where the processing liquid supplier is configured to output the processing liquid cooled to a lower temperature than room temperature, the substrate processing apparatus may further include the gas supplier configured to supply gas to the internal space having a dew-point temperature lower than the temperature of the processing liquid. Flow of the processing liquid at a low temperature causes the risk of dew condensation on the outer wall surface of the processing liquid pipe. The risk of dew condensation can be reduced by using the low dew-point gas for forming an atmosphere around the processing liquid pipe.

In this case, the gas supplier may be configured to supply the gas in a cooled state, for example. This configuration maintains a periphery of the pipe at a low temperature, making it possible to suppress temperature increase of the processing liquid to flow through the processing liquid pipe. This low-temperature gas and an external atmosphere are separated from each other by the exterior pipe, so that dew condensation to occur therebetween can be handled separately.

Furthermore, in this case, the gas supplier may be configured to supply the gas in the internal space in such a way as to conform to a flow direction of the processing liquid in the processing liquid pipe. Both the processing liquid to flow inside the processing liquid pipe and the gas to flow outside the processing liquid pipe are unavoidably subjected to temperature increase as they flow. However, by covering the periphery of the pipe on the upstream side where the temperature of the processing liquid is lowest with the gas at the lowest temperature, it becomes possible to suppress temperature increase of the processing liquid effectively.

Here, if the processing liquid is de-ionized water or pure water, the processing liquid pipe is preferably made of a resin material. Mechanical strength may be more excellent at a metal pipe, for example, than at the resin pipe. However, the resin pipe is more advantageous than the metal pipe in terms of preventing mixture of metal ions into the processing liquid and providing low heat conductivity.

This invention is applicable to every type of substrate processing technique by which a substrate is processed using a temperature-regulated processing liquid. In particular, this invention is effective if a supply path of the processing liquid extends long.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

What is claimed is:

1. A substrate processing apparatus, comprising:
a processing liquid supplier which outputs a temperature-regulated processing liquid;
a substrate processor which processes a substrate using the processing liquid supplied from the processing liquid supplier; and
an interconnecting pipe which connects the processing liquid supplier and the substrate processor to each other and passes the processing liquid therethrough, wherein
the interconnecting pipe includes:
a processing liquid pipe through which the processing liquid flows;
an exterior pipe having a hollow internal space in which the processing liquid pipe is inserted, thereby covering a periphery of the processing liquid pipe; and
a spacer member which is arranged between the processing liquid pipe and the exterior pipe in the internal space and maintains an outer wall surface of the processing liquid pipe and an inner wall surface of the exterior pipe in a non-contact state, and wherein
the spacer member includes a flow path forming part functioning as a gas flow path allowing gas to pass therethrough in a pipe axis direction of the processing liquid pipe in the internal space.

2. The substrate processing apparatus according to claim 1, wherein
the spacer member is provided with a through hole for insertion of the processing liquid pipe.

3. The substrate processing apparatus according to claim 1, wherein the spacer member is provided with a gas passing hole penetrating the spacer member in the pipe axis direction and functioning as the gas flow path.

4. The substrate processing apparatus according to claim 1, wherein
an outer periphery of the spacer member projects outward partially and comes into contact with the inner wall surface of the exterior pipe, and
the gas flow path is a gap between a part of the outer periphery of the spacer member not in contact with the inner wall surface of the exterior pipe and the inner wall surface.

5. The substrate processing apparatus according to claim 2, wherein
an inner periphery of the through hole for insertion of the processing liquid pipe projects inward partially and comes into contact with the outer wall surface of the processing liquid pipe, and
the gas flow path is a gap between a part of the inner periphery of the through hole not in contact with the outer wall surface of the processing liquid pipe and the outer wall surface.

6. The substrate processing apparatus according to claim 1, wherein the spacer member is made of a resin material having an open-cell structure.

7. The substrate processing apparatus according to claim 1, wherein a plurality of the spacer members are arranged at an interval in the pipe axis direction.

8. The substrate processing apparatus according to claim 1, wherein
the processing liquid supplier outputs the processing liquid cooled to a lower temperature than room temperature, and
a gas supplier which supplies gas to the internal space having a dew-point temperature lower than the temperature of the processing liquid is further provided.

9. The substrate processing apparatus according to claim 8, wherein the gas supplier supplies the gas in a cooled state.

10. The substrate processing apparatus according to claim 8, wherein the gas supplier supplies the gas in the internal space in a direction along a flow direction of the processing liquid in the processing liquid pipe.

11. The substrate processing apparatus according to claim 1, wherein the processing liquid is de-ionized water or pure water, and the processing liquid pipe is made of a resin material.
